(19) United States
(12) Patent Application Publication
(10) Pub. No.: US 2025/0351494 A1
(43) Pub. Date: Nov. 13, 2025

(54) METAL-OXIDE-SEMICONDUCTOR CHIP DEVICE

(71) Applicant: IDESYN POWERCHIP CORPORATION, Zhubei City (TW)

(72) Inventors: YUNG-SZU SU, Zhubei City (TW); TIEN-LI CHEN, Zhubei City (TW); YI-HSIUNG LIN, Zhubei City (TW); JING-YUE CHEN, Zhubei City (TW); SHIH-CHIEH CHIEN, Zhubei City (TW)

(21) Appl. No.: 19/188,762

(22) Filed: Apr. 24, 2025

(30) Foreign Application Priority Data
May 9, 2024 (TW) 113117175

(51) Int. Cl. H10D 62/17; H10D 30/63; H10D 62/80; H10D 64/23; H10D 64/27

(52) U.S. Cl. CPC H10D 62/292; H10D 30/63; H10D 62/875; H10D 64/252; H10D 64/519

(57) ABSTRACT

In a metal-oxide-semiconductor chip device first and second source structures are provided on a first side of the semiconductor substrate as a pair. The drain structure is provided on a second side of the semiconductor substrate. The second side faces away from the first source structure and the second source structure. A first channel structure is provided between and separates the first source structure and the semiconductor substrate. A second channel structure is provided between and separates the second source structure and the semiconductor substrate. A gate structure is provided on the first side of the semiconductor substrate. The first and second channel structures are configured as mirror images of each other, and a wide-width area and a narrow-width area are formed between the first and second channel structures as a result of varied spacing between the first and second channel structures.

### BACKGROUND OF THE INVENTION

### 1. Technical Field

The present invention relates to a metal-oxide-semiconductor chip device. More particularly, the invention relates to a metal-oxide-semiconductor chip device whose channel structures are designed to increase current density and reduce the ON resistance.

### 2. Description of Related Art

In the field of power electronics, power devices that are in charge of switch control are key to performance, and silicon-based materials have occupied a dominant position in this field for a long time. However, as the power densities in applications and the speed (frequency) of switching keep increasing, and power consumption requirements become more and more stringent, the designs of silicon-based devices are approaching their theoretical limits in terms of performance. To find a solution, efforts in the industry have been directed mostly to materials, the objective being to find new semiconductor materials that can be used in place of silicon, and in consequence, wide-bandgap semiconductors such as silicon carbide and gallium nitride—also known as third-generation semiconductors—have gradually attracted people's attention. Silicon carbide, in particular, has unparalleled advantages in power semiconductor devices thanks to many of its properties.

Take automotive applications as a specific example, replacing silicon-based devices with silicon carbide-based counterparts in electric drive inverters can reduce efficiency losses at the device level by up to 80%. It is estimated that the power consumption of an electric vehicle can be reduced by 5%-10% if the inverter of the vehicle uses silicon carbide-based power devices. All things considered, although the cost of an inverter module will increase because of the use of silicon carbide, there will nevertheless be a significant reduction in battery cost, heat dissipation cost, and space utilization cost. A side from inverters, silicon carbide-based power devices can be used in the on-board chargers (OBC) and power conversion (DC/DC) systems of electric vehicles, among many others.

When it comes to material improvement, however, there has been no further breakthrough on the market. The existing metal-oxide-semiconductor chip devices that use a common straight channel design have reached their limits regarding effective current density and chip size reduction, and failure to increase effective current density has led to a low price-performance ratio and hence low competitiveness.

### BRIEF SUMMARY OF THE INVENTION

The primary objective of the present invention is to provide a metal-oxide-semiconductor chip device, comprising a semiconductor substrate. The semiconductor substrate comprises a first source structure and a second source structure, a first channel structure and a second channel structure, and a gate structure. The first source structure and the second source structure are provided on a first side of the semiconductor substrate as a pair. The drain structure is provided on a second side of the semiconductor substrate, wherein the second side faces away from the first source structure and the second source structure. The first channel structure is provided between and separates the first source structure and the semiconductor substrate, and the second channel structure is provided between and separates the second source structure and the semiconductor substrate. The gate structure is provided on the first side of the semiconductor substrate and in contact with the first channel structure, the first source structure, the second channel structure, and the second source structure. Wherein the first channel structure and the second channel structure are configured as mirror images of each other, and at least one wide-width area and at least one narrow-width area are formed between the first channel structure and the second channel structure as a result of varied spacing between the first channel structure and the second channel structure.

Furthermore, the semiconductor substrate comprises, sequentially from the second side to the first side, an n+ substrate and an n epitaxial layer.

Furthermore, the first source structure comprises a first n+ well area and a first metal silicide layer provided on the first n+ well area, and the second source structure comprises a second n+ well area and a second metal silicide layer provided on the second n+ well area.

Furthermore, the metal-oxide-semiconductor chip device further comprises an electrode structure, wherein the electrode structure is configured as a bridge between, and has two ends separately connected to, the first metal silicide layer of the first source structure and the second metal silicide layer of the second source structure.

Furthermore, the first channel structure comprises a first p channel area and a first p+ doped area, the first p channel area is provided on a side of the first n+ well area that is adjacent to the second n+ well area, and the first p+ doped area is provided on a side of the first n+ well area that is far from the second n+ well area; and wherein the second channel structure comprises a second p channel area and a second p+ doped area, the second p channel area is provided on a side of the second n+ well area that is adjacent to the first n+ well area, and the second p+ doped area is provided on a side of the second n+ well area that is far from the first n+ well area.

Furthermore, the gate structure comprises an insulating layer provided on the first side of the semiconductor substrate and an electrically conductive layer provided on the insulating layer.

Furthermore, the insulating layer is in contact with a surface of the first side of the semiconductor substrate and is in contact with, sequentially from one end to another end of the insulating layer, the first n+ well area, the first p channel area, the n epitaxial layer, the second p channel area, and the second n+ well area.

Furthermore, the first channel structure and the second channel structure are serrated structures configured as mirror images of each other.

Furthermore, the first channel structure and the second channel structure are wave-shaped structures configured as mirror images of each other.

Furthermore, the first channel structure and the second channel structure are comb-shaped structures configured as mirror images of each other.

Thus, the present invention allows the effective cross-sectional areas of the channels to be enlarged in comparison with those of the prior art and, given the same chip size, can provide an effective increase in current density. The invention also allows the cross-sectional area of the J FET area to be enlarged to further increase the effective cross-sectional areas of the channels and current density.

### BRIEF DESCRIPTION OF THE SEVERAL VIEWS OF THE DRAWINGS

FIG. 1 is a partial sectional perspective view of the metal-oxide-semiconductor chip device of the present invention.

FIG. 2 is an exploded view showing the structure of the first embodiment of the metal-oxide-semiconductor chip device of the present invention.

FIG. 3 is a top view showing the channel shapes of the first embodiment of the metal-oxide-semiconductor chip device of the present invention.

FIG. 4 is a top view showing the channel shapes of the second embodiment of the metal-oxide-semiconductor chip device of the present invention.

FIG. 5 is a top view showing the channel shapes of the third embodiment of the metal-oxide-semiconductor chip device of the present invention.

FIG. 6 is a top view showing the channel shapes of the fourth embodiment of the metal-oxide-semiconductor chip device of the present invention.

FIG. 7 is a top view showing the channel shapes of the fifth embodiment of the metal-oxide-semiconductor chip device of the present invention.

### DETAILED DESCRIPTION OF THE INVENTION

To provide a complete and detailed account of the technical contents of the present invention, some implementation modes and embodiments of the invention are described below. It should be understood, however, that the following description is not intended to provide the only ways in which the invention can be implemented or used. If a person of ordinary skill in the art can easily understand the essential technical contents of the invention from the following description and changes or modifies the invention in various ways that do not depart from the spirit or scope of the invention, all such alternative modes of implementation shall fall within the scope of the appended claims of the invention.

In the description of the present invention, the terms “a” and “the” can be construed as referring to a plurality unless otherwise stated in the context. Besides, in the present specification and the appended claims, the phrase “provided on an object” can be viewed as being in direct or indirect contact with a surface of the object by adhesive attachment or by other means unless otherwise specified, wherein the definition of the surface should be determined according to the context as well as the common knowledge of a person of ordinary skill in the art.

In the description of the present invention, unless otherwise specified in the context, the terms “comprise,” “include,” “have,” and “contain” are inclusive or open-ended and do not exclude elements or steps that are not stated.

In the description of the present invention, terms that are used to indicate directions or positional relationships, such as “middle,” “upper,” “lower,” “front,” “rear,” “left,” “right,” “vertical,” “horizontal,” “top,” “bottom,” “inner,” and “outer,” make reference to the directions or positional relationships shown in the accompanying drawings. Such terms are used only to facilitate description of the invention and to simplify the description, but not to indicate or imply that the device or element in question must have a particular direction or position or be operated in a particular orientation. These terms, therefore, should not be understood as restrictive of the invention. In addition, it should be pointed out that although some of the structural features are shown in the present application in exploded view, it is not necessarily feasible or possible in practice to disassemble the finished product.

The metal-oxide-semiconductor chip device of the present invention can be used in high-frequency high-voltage products such as inverters, rectifiers, electric vehicles, plug-in hybrid electric vehicles (PHEVs), charging stations, smart electrical grids, energy storage equipment, rail transport-related products, and other high-frequency high-power electronic products. The invention has no limitation on the scope of use of the metal-oxide-semiconductor chip device.

The major material of the metal-oxide-semiconductor chip device of the present invention may include, but is not limited to, silicon (Si), silicon carbide (SIC), gallium nitride (GaN), gallium (III) oxide (Ga₂O₃), a diamond power semiconductor material (diamond C), or other similar materials; the invention has no limitation in this regard. The device type of the metal-oxide-semiconductor chip device of the invention may be, for example, vertical double-diffused metal-oxide semiconductor (VDMOS), metal-oxide-semiconductor field-effect transistor (MOSFET), insulated-gate bipolar transistor (IGBT), or other similar device types; the invention has no limitation in this regard, either. The gate structure design used in the invention may be, but is not limited to, a planar design or a trench design; the invention also has no limitation in this regard.

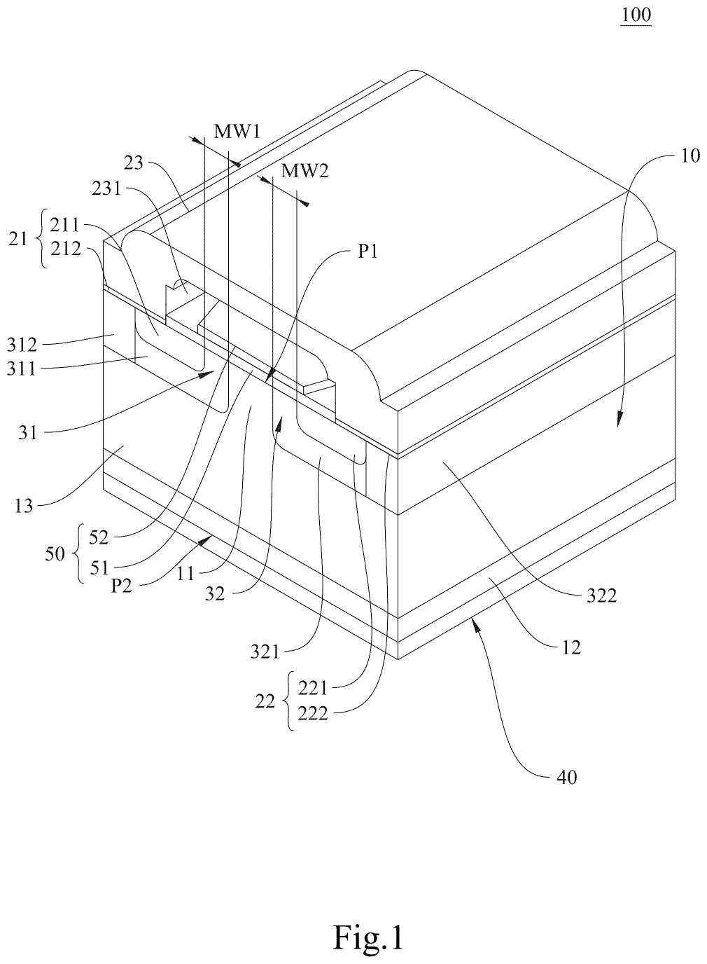

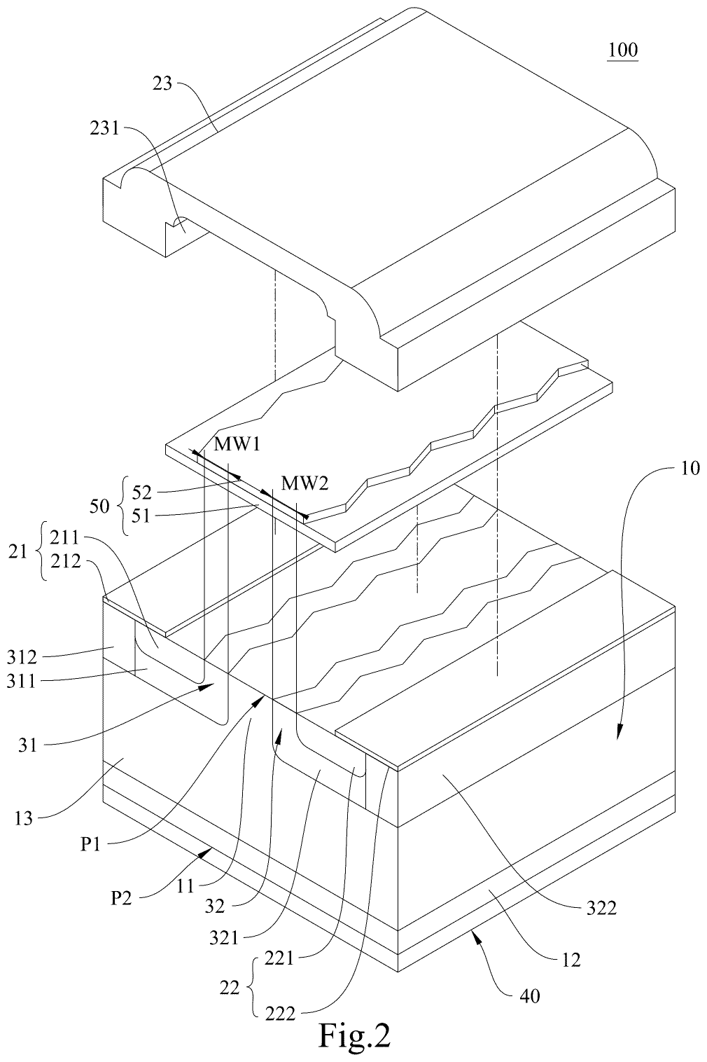

One embodiment of the present invention is detailed as follows. Referring first to FIG. 1 and FIG. 2 for a partial sectional perspective view and an exploded view of the metal-oxide-semiconductor chip device of the invention, this embodiment provides a metal-oxide-semiconductor chip device 100 that essentially includes: a semiconductor substrate 10; a first source structure 21 and a second source structure 22, both provided on the semiconductor substrate 10; a first channel structure 31 and a second channel structure 32, both provided on the semiconductor substrate 10; a drain structure 40; and a gate structure 50.

The first source structure 21 and the second source structure 22 are provided on a first side P1 of the semiconductor substrate 10 as a pair. The drain structure 40 is provided on a second side P2 of the semiconductor substrate 10, i.e., on the opposite side of the side on which the first source structure 21 and the second source structure 22 are provided. Here, the first side P1 refers to a surface of the semiconductor substrate 10 that corresponds to the upper side of FIG. 1, and the second side P2 refers to a surface of the semiconductor substrate 10 that corresponds to the lower side of FIG. 1. These expressions of directions serve only to make the contents of the present invention clear, and it can be understood that the aforesaid positional relationships with respect to the upper and lower sides of FIG. 1 may change when the direction in which the metal-oxide-semiconductor chip device 100 is placed is changed. The invention has no limitation on such changes in direction of the metal-oxide-semiconductor chip device 100.

The first channel structure 31 is provided between the first source structure 21 and the semiconductor substrate 10 in such a way that the first channel structure 31 separates the first source structure 21 from the semiconductor substrate 10 and renders the first source structure 21 into a well structure. The second channel structure 32 is provided between the second source structure 22 and the semiconductor substrate 10 in such a way that the second channel structure 32 separates the second source structure 22 from the semiconductor substrate 10 and renders the second source structure 22 into a well structure. The gate structure 50 is provided on the first side P1 of the semiconductor substrate 10 and is in contact with the first channel structure 31, the first source structure 21, the second channel structure 32, and the second source structure 22 such that, when an externally applied electric field is applied to the gate, an electron layer (or electron hole layer) will be formed in each of the first channel structure 31 and the second channel structure 32, thus allowing the first source structure 21 to be electrically connected through the semiconductor substrate 10 to the drain structure 40, and the second source structure 22 to be electrically connected through the semiconductor substrate 10 to the drain structure 40.

In this embodiment, the area of the semiconductor substrate 10 that lies between the first channel structure 31 and the second channel structure 32 is a junction field-effect transistor (JFET) area 11. The name of the JFET area 11, however, does not mean that the metal-oxide-semiconductor chip device 100 of the present invention is a JFET; rather, the name means that, with the first channel structure 31 and the second channel structure 32 provided symmetrically on two sides of the semiconductor substrate 10, the portion of the semiconductor substrate 10 that is sandwiched between the first channel structure 31 and the second channel structure 32 has properties similar to those of a JFET.

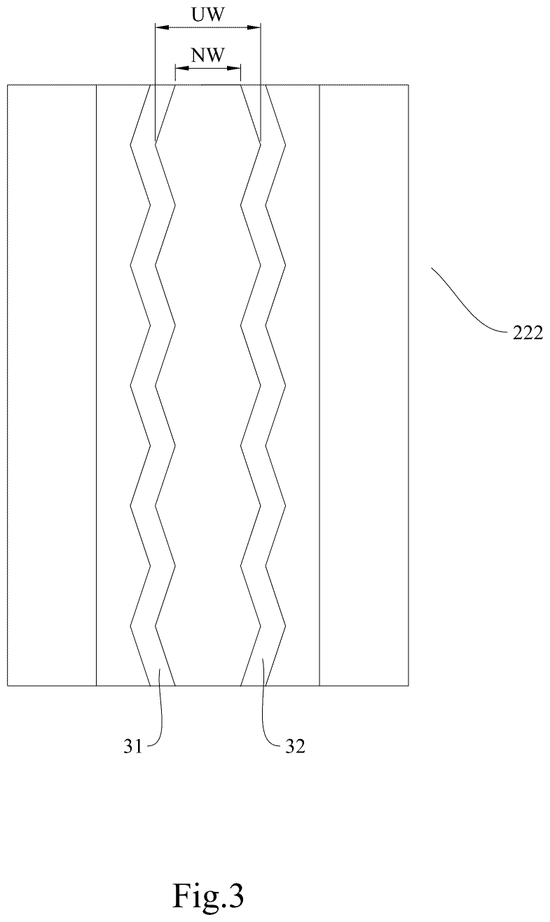

Referring to FIG. 3 for a top view showing the channel shapes of the first embodiment of the metal-oxide-semiconductor chip device of the present invention, the first channel structure 31 and the second channel structure 32 in the invention are configured as mirror images of each other. Here, the mirror-image configuration refers to a configuration in which the shapes of the first channel structure 31 and of the second channel structure 32 are mirror images of each other in top view (as shown in FIG. 2), but not a configuration in which the shapes of the first channel structure 31 and of the second channel structure 32 are mirror images of each other in sectional view (as shown in FIG. 1). At least one wide-width area UW and at least one narrow-width area NW are formed between the first channel structure 31 and the second channel structure 32 as a result of the varied spacing between the two channel structures. In one embodiment, the greatest width of the wide-width area UW is 2.1 μm to 2.3 μm, such as but not limited to 2.10 μm, 2.11 μm, 2.12 μm, 2.13 μm, 2.14 μm, 2.15 μm, 2.16 μm, 2.17 μm, 2.18 μm, 2.19 μm, 2.20 μm, 2.21 μm, 2.22 μm, 2.23 μm, 2.24 μm, 2.25 μm, 2.26 μm, 2.27 μm, 2.28 μm, 2.29 μm, or 2.30 μm; the invention has no limitation in this regard. In one embodiment, the smallest width of the narrow-width area NW is 1.1 μm to 1.3 μm, such as but not limited to 1.10 μm, 1.11 μm, 1.12 μm, 1.13 μm, 1.14 μm, 1.15 μm, 1.16 μm, 1.17 μm, 1.18 μm, 1.19 μm, 1.20 μm, 1.21 μm, 1.22 μm, 1.23 μm, 1.24 μm, 1.25 μm, 1.26 μm, 1.27 μm, 1.28 μm, 1.29 μm, or 1.30 μm; the invention has no limitation in this regard, either. When the narrow-width area NW is configured to receive an externally applied electric field, pinch-off will take place in the narrow-width area NW when the externally applied electric field is applied, with a source-to-drain current Isp flowing through the wide-width area UW. To achieve this configuration, the actual widths of the wide-width area UW and of the narrow-width area NW should be determined according to the doping concentrations of a first p channel area 311 in the first channel structure 31 and of a second p channel area 321 in the second channel structure 32. Therefore, the invention imposes no limitation on the width of the wide-width area UW or of the narrow-width area NW; the widths of the wide-width area UW and of the narrow-width area NW depend on whether or not the intended configuration allows a current to flow through the wide-width area UW and pinch-off to take place in the narrow-width area NW when an externally applied electric field is applied. In addition, it should be pointed out that the portions of the first channel structure 31 and of the second channel structure 32 that form the wide-width area UW and the narrow-width area NW are mainly those portions on the two lateral sides of the JFET area 11, and that the invention has no limitation on the shape of the remaining portion of the first channel structure 31 or of the second channel structure 32.

While the previous paragraph only describes the first channel structure 31 and the second channel structure 32 as mirror-image structures with varied spacing between them, the first source structure 21 and the second source structure 22 and/or the electrically conductive layers (e.g., metal silicide layers) on the first source structure 21 and on the second source structure 22 are shaped to match the designs of the first channel structure 31 and of the second channel structure 32. Similarly, the gate structure 50 may also be designed to match the shapes of the first channel structure 31 and of the second channel structure 32 and therefore have areas that are different in width; the present invention has no limitation in this regard.

Referring back to FIG. 1, the structural features of the present invention are described below with reference to an embodiment having an npn structure by way of example. In this embodiment, the semiconductor substrate 10 includes, sequentially from the second side P2 to the first side P1, an n+ substrate 12 and an n epitaxial layer 13; the first source structure 21 includes a first n+ well area 211 and a first metal silicide layer 212 provided on the first n+ well area 211; and the second source structure 22 includes a second n+ well area 221 and a second metal silicide layer 222 provided on the second n+ well area 221. In this embodiment, the metal-oxide-semiconductor chip device 100 further includes an electrode structure 23 that is configured as a bridge between, and has two ends separately connected to, the first metal silicide layer 212 of the first source structure 21 and the second metal silicide layer 222 of the second source structure 22. A middle portion of the electrode structure 23 is formed as a hollow groove 231 to prevent contact between the electrode structure 23 and the gate structure 50. In one embodiment, the material of the electrode structure 23 may be aluminum or other electrically conductive materials; the invention has no limitation in this regard. It should be pointed out that although the illustrated embodiment has an npn structure, it is feasible in practice to use a pnp structure instead; the invention has no limitation on such variations.

In this embodiment, the first channel structure 31 includes a first p channel area 311 provided on a side of the first n+ well area 211 that is adjacent to the second n+ well area 221 (i.e., adjacent to the J FET area 11) and a first p+ doped area 312 provided on a side of the first n+ well area 211 that is far from the second n+ well area 221 (i.e., far from the J FET area 11), wherein the first p channel area 311 and the first p+ doped area 312 surround the bottom side of the first n+ well area 211; the second channel structure 32 includes a second p channel area 321 provided on a side of the second n+ well area 221 that is adjacent to the first n+ well area 211 (i.e., adjacent to the J FET area 11) and a second p+ doped area 322 provided on a side of the second n+ well area 221 that is far from the first n+ well area 211 (i.e., far from the J FET area 11), wherein the second p channel area 321 and the second p+ doped area 322 surround the bottom side of the second n+ well area 221; and the gate structure 50 includes an insulating layer 51 provided on the first side P1 of the semiconductor substrate 10 (i.e., on an upper surface of the J FET area 11) and an electrically conductive layer 52 provided on the insulating layer 51. According to the foregoing configuration, the insulating layer 51 is in contact with the surface of the first side P1 of the semiconductor substrate 10, or more particularly is in contact with, sequentially from one end to an opposite end of the insulating layer 51 (e.g., from left to right as shown in FIG. 1), the first n+ well area 211, the first p channel area 311, the n epitaxial layer 13 (including the JFET area 11), the second p channel area 321, and the second n+ well area 221.

In this embodiment, the first p channel area 311 is L-shaped, extends from the first n+ well area 211 to a region between the first n+ well area 211 and the J FET area 11, and has a top side in contact with the insulating layer 51 of the gate structure 50; and the second p channel area 312 is L-shaped, extends from the second n+ well area 221 to a region between the second n+ well area 221 and the J FET area 11, and has a top side in contact with the insulating layer 51 of the gate structure 50. In one embodiment, the width of each of the first p channel area 311 and the second p channel area 312 is 0.35 μm to 0.45 μm, and the “width” of each of the first p channel area 311 and the second p channel area 312 refers to the width of only the region of the first p channel area 311 or of the second p channel area 312 that can form a channel, i.e., the region whose width is marked as MW1 or MW2 in FIG. 1. This width may be, for example but not limited to, 0.35 μm, 0.36 μm, 0.37 μm, 0.38 μm, 0.39 μm, 0.40 μm, 0.41 μm, 0.42 μm, 0.43 μm, 0.44 μm, or 0.45 μm; the present invention has no limitation in this regard.

Different embodiments of the channel structures in the present invention are described below with reference to FIG. 3 to FIG. 7, which are top views showing the channel shapes of the first to fifth embodiments of the metal-oxide-semiconductor chip device of the invention. Please note that, to facilitate description, the drawings in FIG. 3 to FIG. 7 are simplified depictions of only the channel shapes and are not intended to limit the actual appearance of the metal-oxide-semiconductor chip device 100 of the invention.

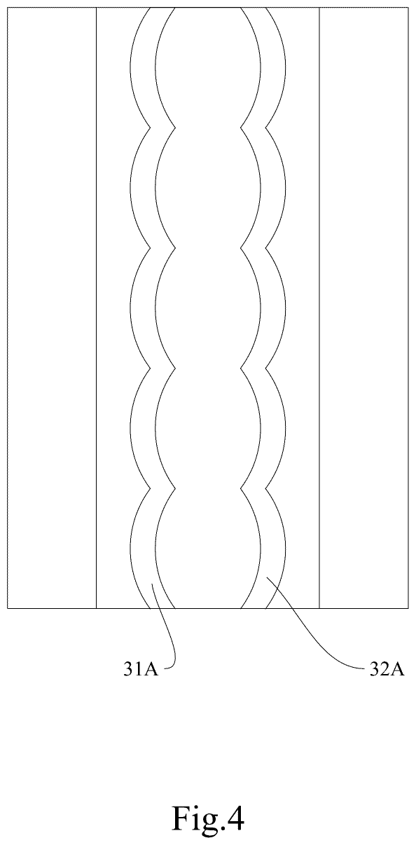

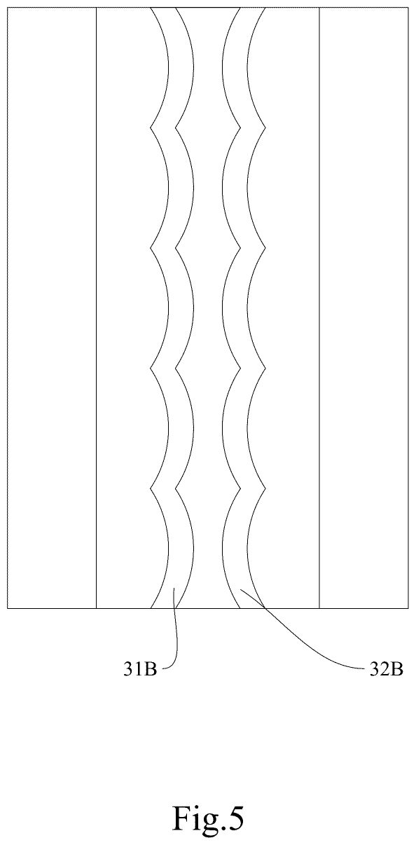

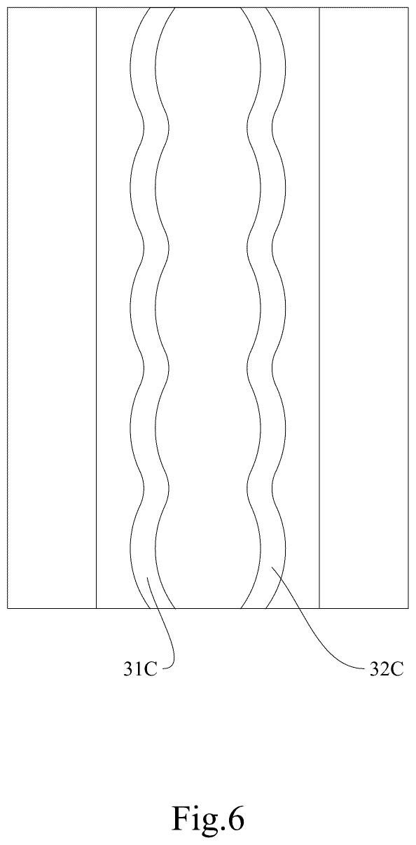

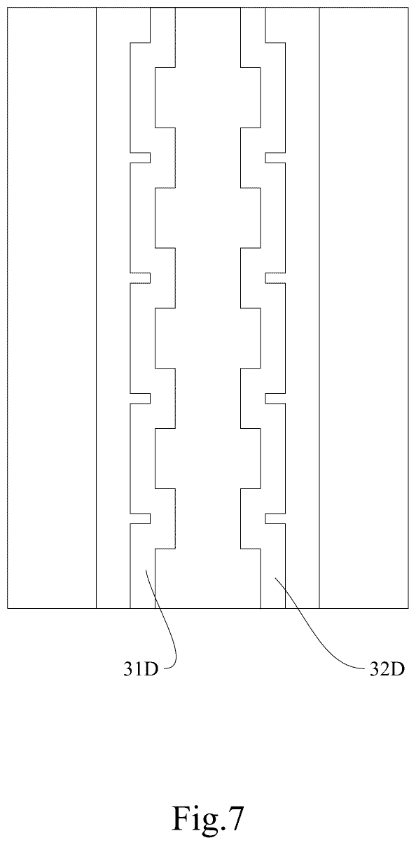

In one embodiment as shown in FIG. 3, the first channel structure 31 and the second channel structure 32 may be, but are not limited to, serrated structures that are mirror images of each other. In another embodiment as shown in FIG. 4, the first channel structure 31A and the second channel structure 32A may be, but are not limited to, wave-shaped structures that are mirror images of each other and are in the form of ripples, with the pointed portions facing inward. In another embodiment as shown in FIG. 5, the first channel structure 31B and the second channel structure 32B may be, but are not limited to, wave-shaped structures that are mirror images of each other, are in the form of ripples, and are different from those in the embodiment in FIG. 4 in that the pointed portions face outward. In another embodiment as shown in FIG. 6, the first channel structure 31C and the second channel structure 32C may be, but are not limited to, wave-shaped structures that are mirror images of each other and are in the form of sinusoidal waves. In another embodiment as shown in FIG. 7, the first channel structure 31D and the second channel structure 32D may be, but are not limited to, square-wave-shaped structures that are mirror images of each other. The aforesaid shapes are only examples corresponding to some embodiments of the present invention. Any simple change made to those shapes shall fall within the scope of the patent protection sought by the applicant.

According to the above, the present invention allows the effective cross-sectional areas of the channels to be enlarged in comparison with those of the prior art and, given the same chip size, can provide an effective increase in current density. The invention also allows the cross-sectional area of the JFET area to be enlarged to further increase the effective cross-sectional areas of the channels and current density.

While the present invention has been detailed above, the foregoing embodiments are only some preferred ones of the invention and are not intended to limit the scope of the invention. In other words, any equivalent change or modification that is made according to the claims of the invention shall fall within the scope of the invention.

1. A metal-oxide-semiconductor chip device, comprising:
a semiconductor substrate;
a first source structure and a second source structure, provided on a first side of the semiconductor substrate as a pair;
a drain structure provided on a second side of the semiconductor substrate, wherein the second side faces away from the first source structure and the second source structure;
a first channel structure and a second channel structure, wherein the first channel structure is provided between and separates the first source structure and the semiconductor substrate, and the second channel structure is provided between and separates the second source structure and the semiconductor substrate; and
a gate structure provided on the first side of the semiconductor substrate and in contact with the first channel structure, the first source structure, the second channel structure, and the second source structure;
wherein the first channel structure and the second channel structure are configured as mirror images of each other, and at least one wide-width area and at least one narrow-width area are formed between the first channel structure and the second channel structure as a result of varied spacing between the first channel structure and the second channel structure.

2. The metal-oxide-semiconductor chip device of claim 1, wherein the semiconductor substrate comprises, sequentially from the second side to the first side, an n+ substrate and an n epitaxial layer.

3. The metal-oxide-semiconductor chip device of claim 2, wherein the first source structure comprises a first n+ well area and a first metal silicide layer provided on the first n+ well area, and the second source structure comprises a second n+ well area and a second metal silicide layer provided on the second n+ well area.

4. The metal-oxide-semiconductor chip device of claim 3, further comprising an electrode structure, wherein the electrode structure is configured as a bridge between, and has two ends separately connected to, the first metal silicide layer of the first source structure and the second metal silicide layer of the second source structure.

5. The metal-oxide-semiconductor chip device of claim 3, wherein the first channel structure comprises a first p channel area and a first p+ doped area, the first p channel area is provided on a side of the first n+ well area that is adjacent to the second n+ well area, and the first p+ doped area is provided on a side of the first n+ well area that is far from the second n+ well area; and wherein the second channel structure comprises a second p channel area and a second p+ doped area, the second p channel area is provided on a side of the second n+ well area that is adjacent to the first n+ well area, and the second p+ doped area is provided on a side of the second n+ well area that is far from the first n+ well area.

6. The metal-oxide-semiconductor chip device of claim 5, wherein the gate structure comprises an insulating layer provided on the first side of the semiconductor substrate and an electrically conductive layer provided on the insulating layer.

7. The metal-oxide-semiconductor chip device of claim 6, wherein the insulating layer is in contact with a surface of the first side of the semiconductor substrate and is in contact with, sequentially from one end to another end of the insulating layer, the first n+ well area, the first p channel area, the n epitaxial layer, the second p channel area, and the second n+ well area.

8. The metal-oxide-semiconductor chip device of claim 1, wherein the first channel structure and the second channel structure are serrated structures configured as mirror images of each other.

9. The metal-oxide-semiconductor chip device of claim 1, wherein the first channel structure and the second channel structure are wave-shaped structures configured as mirror images of each other.

10. The metal-oxide-semiconductor chip device of claim 1, wherein the first channel structure and the second channel structure are square-wave-shaped structures configured as mirror images of each other.
